(19) United States
(12) Patent Application Publication
(10) Pub. No.: US 2020/0230581 A1
(43) Pub. Date: Jul. 23, 2020

(54) NANOCATALYSTS FOR ELECTROCHEMICAL HYDROGEN PRODUCTION AND CATALYST SCREENING METHODS

(71) Applicant: NORTHWESTERN UNIVERSITY, Evanston, IL (US)

(72) Inventors: Chad A. Mirkin, Wilmette, IL (US); Yijin Kang, Naperville, IL (US); Liliang Huang, Evanston, IL (US)

(21) Appl. No.: 16/651,674

(22) PCT Filed: Oct. 3, 2018
(86) PCT No.: PCT/US18/54115

§ 371 Date: Mar. 27, 2020

Related U.S. Application Data
(60) Provisional application No. 62/567,714, filed on Oct. 3, 2017.

(51) Int. Cl. B01J 23/89; B01J 37/02; B01J 35/00; B01J 37/08; G03F 7/00; C25B 1/02; C25B 15/02

(52) U.S. Cl. CPC B01J 23/8933; B01J 37/0221; B01J 35/006; B01J 21/18; G03F 7/0002; C25B 1/02; C25B 15/02; B01J 37/08

(57) ABSTRACT

Disclosed herein are trimetallic PtAu-based nanocatalysts for electrochemical hydrogen production and screening methods thereof. Nanocatalysts are produced through a polymer pen lithography (PPL) technique, which enables large-scale fabrication of nanoparticle arrays with programmable specifications such as size, shape, and composition, providing a route to the high-throughput screening and discovery of new catalysts.

### STATEMENT OF GOVERNMENTAL INTEREST

This invention was made with government support under FA9550-16-1-0150 awarded by the Air Force Office of Scientific Research and DBI1353682 awarded by the National Science Foundation. The government has certain rights in the invention.

### BACKGROUND

Catalyst design is extremely challenging, especially when nanoparticles are the active structures. In addition to composition, the size, shape, and surface structure can be important considerations. For poly-elemental systems, the design challenges are substantially greater since the configurational complexity in these alloy systems adds significant new degrees of freedom to structure-function relationships. For example, the alloying and phase segregating behavior of poly-elemental systems can lead to new and unexpected catalytic properties. This observation presents several significant challenges. First, with many solution based synthesis protocols, it is difficult, if not impossible, to control “phase purity” in multi-metallic nanoparticle systems, since many potentially catalytically active structures are kinetic rather than thermodynamic products. Second, when one considers particle size, composition, shape, and degree of alloying or phase segregation, the sheer number of possibilities is daunting. To address this challenge, ways of making poly-elemental particles and controlling their state of alloying or phase-segregation combined with methods for screening them and reducing the numbers that need to be produced at scale to validate properties of interest must be developed. This requires either a combinatorial approach or the use of theory to minimize targets of opportunity, or a combination of both.

### SUMMARY

Provided herein are catalysts comprising PtAuX and having a hydrogen binding energy lower than 0.0 eV, wherein X is a transition metal other than Pt and Au.

In various cases, the hydrogen binding energy is from −0.1 to −0.6 eV, or from −0.2 to −0.4 eV. In various cases, X is Cu or Ni. In various cases, the catalyst is an alloy or in the form of a phase-separated heterostructure. In various cases, the alloy is a homogeneous alloy. In various cases, the catalyst is in a 1:1:1 ratio. In various cases, the catalyst is in the form of a nanoparticle. In various cases, the nanoparticle has a diameter of 10 to 20 nm. In various cases, the catalyst is loaded onto a support. In various cases, the support is carbon black or glassy carbon.

Also provided herein is a method of reducing an organic compound comprising contacting the compound with a reducing agent (e.g., H₂) in the presence of a catalyst disclosed herein to form a reduced organic compound.

Also provided herein is a method including (a) coating a tip of a tip array with an ink comprising a metal precursor and a polymer solution; (b) contacting a substrate surface for a contacting period of time and at a contacting pressure with the coated tip of the tip array to deposit the ink onto the substrate surface to form a set of indicia, the indicia of being substantially uniform in size; (c) heating the tip array under conditions sufficient to form nanoparticles from the metal precursor; and (d) using the substrate surface comprising the nanoparticles in a three-electrode cell to assess the nanoparticles as catalysts of a hydrogen evolution reaction. In various cases, the method further includes contacting the substrate surface with a tip array coated with a second ink comprising a second metal precursor, prior to step (c), and the second metal precursor forms a second nanoparticle. In various cases, the substrate includes glassy carbon. In various cases, the polymer solution includes PEO-b-P2VP. In various cases, the metal precursor includes two or more metals or metal salts, or three metals or metal salts. In various cases, the conditions sufficient to form nanoparticles include a two-step annealing process. In various cases, the tip array includes an elastomeric polymer material.

### BRIEF DESCRIPTION OF THE DRAWINGS

FIG. 1 shows a process for synthesizing nanoparticles by SPBCL and then studying their HER catalytic properties. Briefly, (i) PPL is used to pattern poly(ethylene oxide)-b-poly(2-vinylpyridine) (PEO-b-P2VP) nanoreactors, loaded with the appropriate metal salts, onto a glassy carbon substrate. Each nanoreactor has a near identical volume and contains approximately the same number and type of atoms. (ii) The metal ion contents of the nanoreactors are thermally transformed into nanoparticles under a reducing environment. (iii) The patterned substrate is then used as a working electrode in a three-electrode cell to study HER catalysis.

FIG. 2 shows (a) dark-field optical microscopy image of uniformly patterned nanoreactor arrays by SPBCL, (b) AFM topographical image of uniformly patterned nanoreactor arrays by SPBCL, (c) SEM image of uniformly patterned nanoreactor arrays by SPBCL, and (d) SEM image of an array of PtAuCu trimetallic nanoparticles on glassy carbon.

FIG. 3 shows HAADF-STEM images and EDS maps of multimetallic nanoparticles synthesized by SPBCL. (a) PtAu, (b) PtCu, (c) PtNi, (d) PtAuCu and (e) PtAuNi. Representative HAADF-STEM images of arrays of 2×2 nanoparticle arrays are shown in (d) and (e). Dotted circles are used to highlight the position of the nanoparticles as a guide to the eye. Only one nanoparticle is observed at each site. Scale bars: 5 nm.

FIG. 4 shows (a) representative HER polarization curves (from left to right: PtCu, PtAuNi, PtNi, PtAu, Pt, PtAuCu) and statistical results from all HER measurements showing that (b) the overpotential difference at 10 mA cm⁻² of various SPBCL-synthesized multimetallic nanoparticle catalysts (the overpotential of SPBCL-synthesized Pt is used as a comparison), and (c) current densities at the overpotential of 0.4 V (the current densities are normalized to the content of Pt in each particle). (d) A volcano plot, in which the exchange current densities are calculated from Tafel plots and the HBE values are calculated by DFT.

FIG. 5 shows (a) TEM and (b) EDS maps of PtAuCu nanocatalyst, (c) XRD patterns of as-synthesized PtAuCu nanoparticles, in which the main component of PtAuCu is marked by the reference lines and the minor component of Au is marked by *. (d) HER polarization curves of PtAuCu/C (right-side curve) and Pt/C (left-side curve). Scale bar in (b): 5 nm.

FIG. 6 shows energy-dispersive X-ray spectra of the SPBCL synthesized metal nanoparticles, and an HRTEM image of SPBCL synthesized PtAuCu nanoparticle.

FIG. 7 shows an XRD pattern (bottom) of solution phase synthesized PtAuNi nanoparticles, indicating the nanoparticles are a mixture of Au nanoparticles and an A1 phase alloy; upon annealing, the XRD pattern (top) reveals a fcc Au phase and a PtNi intermetallic phase (*), as well as other phase impurities.

FIG. 8 shows a) hydrogen binding energies on different adsorption sites for different systems. b) and c) top and side view for the slab models of bi-metallic (from top—first and third layer: Cu, second and fourth layer: Pt) and tri-metallic (top layer, left to right: Pt, Cu, Au, Pt, Cu, Au) alloyed surfaces.

FIG. 9 shows a) top view and side view of a slab model with (3×4) unit cell to calculate hydrogen binding energies on the interface of Pt—Ni and Au (layers from top to bottom: Au, Au, Pt, Ni, Au, Au, Pt, Ni). The surface of Pt—Ni—Au interface has been divided into four regions, 1) Au—Ni region, 2) Au region, 3) Au—Pt region and 4) Pt—Ni region. b) Hydrogen binding energies in each region of the Pt—Ni—Au interface model. As a comparison, hydrogen binding energy on a (3×4) unit cell of Pt—Ni surface was considered. c) Hydrogen binding energies on a tri-metallic alloyed surface of Pt—Ni—Au. d) Exchange current densities as a function of calculated hydrogen binding energies.

FIG. 10 shows energy-dispersive X-ray spectra of the solution phase synthesized PtAuCu nanoparticles. (Ni signal is from the Ni TEM grids).

FIG. 11 shows a cyclic voltammogram (scan rate: 50 mV s⁻¹) of Pt/C (inner trace) and PtAuCu/C (outer trace).

FIG. 12 shows a stability test of PtAuCu/C for HER shows negligible catalyst deactivation after 10,000 cycles (initial scan—right side curve; 10,000^{th} scan—left side curve). iR-correction was not applied during stability test.

### DETAILED DESCRIPTION

Herein, an emerging nanoparticle synthetic tool called scanning probe block copolymer lithography (SPBCL) and density functional theory (DFT) are used to explore three-component particles comprising combinations of Pt, Au, Cu, and Ni. This is a system to evaluate the utility of such an approach since Pt is known to be the best single element catalyst for the hydrogen evolution reaction (HER), and additional elements can be used to tune the H-adsorption properties of the multi-metallic systems.

HER was selected due to its importance in the commercial production of hydrogen. In an acidic electrolyte, the activity of the HER is solely related to the catalyst hydrogen binding energy (HBE). According to the Sabatier principle, an optimal HER catalyst should have an HBE that is neither too strong (e.g. strong adsorbing surface: W, Mo, Fe, Co, Ni, etc.) nor too weak (e.g. weak adsorbing surface: Au, Ag, Cu, etc.). Pt is the best single element catalyst for HER, but in principle, could be further improved if its HBE was reduced. Electronically tuning the d-band structure of Pt by alloying it with other elements has proven to be an effective way of tailoring its adsorption properties. Indeed, alloying Au with Pt reduces the HBE and increases the nobility of the catalyst, thereby enhancing its stability. Adding a third metal into the Pt—Au system may further improve the HBE by providing an additional variable for fine tuning adsorption energy. The addition of a third element provides access to many structures, defined not only by stoichiometry but also by phase (alloying or phase-segregated). To test this hypothesis and identify active HER catalysts, the PtAu-M (M=Ni, Cu) trimetallic system was investigated. DFT calculations were used to evaluate the HBE for potential target particle structures, and then synthesized and evaluated for catalytic properties. Importantly, SPBCL allows one to synthesize particles that are uniform both in terms of stoichiometry and phase. Through this exercise, PtAuCu was identified as having the optimal calculated HBE (based upon a Volcano plot) and correspondingly, the highest measured HER activity.

The catalysts disclosed herein comprise PtAuX, wherein X is a transition metal other than Pt and Au. In some embodiments, X can be Cu or Ni. In some embodiments, X is Cu. In some embodiments, X is Ni.

The catalysts disclosed herein can have a hydrogen binding energy lower than 0.0 eV, e.g., a hydrogen binding energy from −0.1 to −0.6 eV, from −0.1 to −0.3 eV, from −0.2 to −0.4 eV, from −0.3 to −0.5 eV, from −0.1 to −0.4 eV, from −0.2 to −0.5 eV, and from −0.3 to −0.6 eV. In some embodiments, the catalysts disclosed herein have a hydrogen binding energy of about 0.0 eV, about −0.1 eV, about −0.2 eV, about −0.3 eV, about −0.4 eV, about −0.5 eV, or about −0.6 eV, where “about” means the disclosed value±10%. In some embodiments, the hydrogen binding energy is about −0.3 eV.

The catalysts disclosed herein can be in the form of an alloy or in the form of a phase-separated heterostructure. In some embodiments, the catalyst is in the form of homogeneous alloy. In some embodiments, the catalyst is in the form of a phase-separated heterostructure.

In some embodiments, the catalysts disclosed herein include PtAuX in a 1:1:1 molar ratio. As used here, a “1:1:1 molar ratio” includes ratios wherein the components are present in about equal proportions, e.g., in a ratio of 1±0.20:1±0.20:1±0.20, in a ratio of 1±0.15:1±0.15:1±0.15, in a ratio of 1±0.10:1±0.10:1±0.10, or in a ratio of 1±0.05:1±0.05:1±0.05. For example and without intending to be limiting in scope, the term “1:1:1 molar ratio” includes catalysts having the composition Pt₃₇Au₂₉Cu₃₄ and Pt₃₂Au₃₆Ni₃₂.

In some embodiments, the catalysts disclosed herein are in the form of a nanoparticle. In some embodiments, the nanoparticle has a diameter of 10 to 20 nm, e.g., a diameter of 15 to 20 nm. In some embodiments, the nanoparticle has a diameter of 10, 11, 12, 13, 14, 15, 16, 17, 18, 19, or 20 nm.

In some embodiments, the catalysts disclosed herein are loaded onto a support or a substrate. In some embodiments, the support or substrate includes a carbon support, e.g., carbon black or glassy carbon.

Also disclosed are methods of using the catalysts disclosed herein. In some embodiments, the method is a method of reducing an organic compound comprising contacting the compound with a reducing agent (e.g., H₂) in the presence of a catalyst disclosed herein to form a reduced organic compound. In some embodiments, a catalyst disclosed herein is useful in a hydrogen evolution reaction (HER).

Also disclosed are methods of making a catalyst disclosed herein. In some embodiments, the method includes (a) coating a tip of a tip array with an ink containing a metal precursor and a polymer solution; (b) contacting a substrate surface for a contacting period of time and at a contacting pressure with the coated tip of the tip array to deposit the ink onto the substrate surface to form a set of indicia, the indicia of being substantially uniform in size; and (c) heating the tip array under conditions sufficient to form nanoparticles from the metal precursor. In some embodiments, the method further includes using the substrate surface comprising the nanoparticles in a three-electrode cell to assess the nanoparticles as catalysts of a hydrogen evolution reaction.

As used herein, the term “metal precursor” refers to one or more metals, compounds, or salts including a constituent metal of a catalyst described herein, e.g., a Pt metal, compound, or salt, an Au metal, compound, or salt, a Cu metal, compound, or salt, and a Ni metal, compound, or salt. In some embodiments, the metal precursor is Pt(acac)₂, HAuCl₄, Cu(acac)₂, H₂PtCl₆.6H₂O, HAuCl₄.3H₂O, Cu(NO₃)₂.3H₂O, or Ni(NO₃)₂.6H₂O. In some embodiments, a “metal precursor” as used herein can include one metal, compound, or salt, two metals, compounds, or salts, or three metals, compounds, or salts.

As used herein, the term “polymer solution” includes aqueous or non-aqueous solutions comprising a polymer. In some embodiments, a polymer solution comprises a water soluble polymer, e.g., a poly(ethylene oxide) or poly(ethylene glycol) polymer. In some embodiments, the polymer solution is an aqueous solution of poly(ethylene oxide)-block-poly(2-vinylpyridine) (PEO-b-P2VP).

In some embodiments, catalysts disclosed herein are produced as nanoparticles formed by heating an ink containing a metal precursor and a polymer solution under conditions sufficient to form nanoparticles from the metal precursor. In some embodiments, the conditions sufficient to form nanoparticles from the metal precursor include one or more heating and cooling steps. In some embodiments, the conditions include more than one heating and cooling step, e.g., a two-step annealing process.

### Preparation of Uniform Model Catalysts

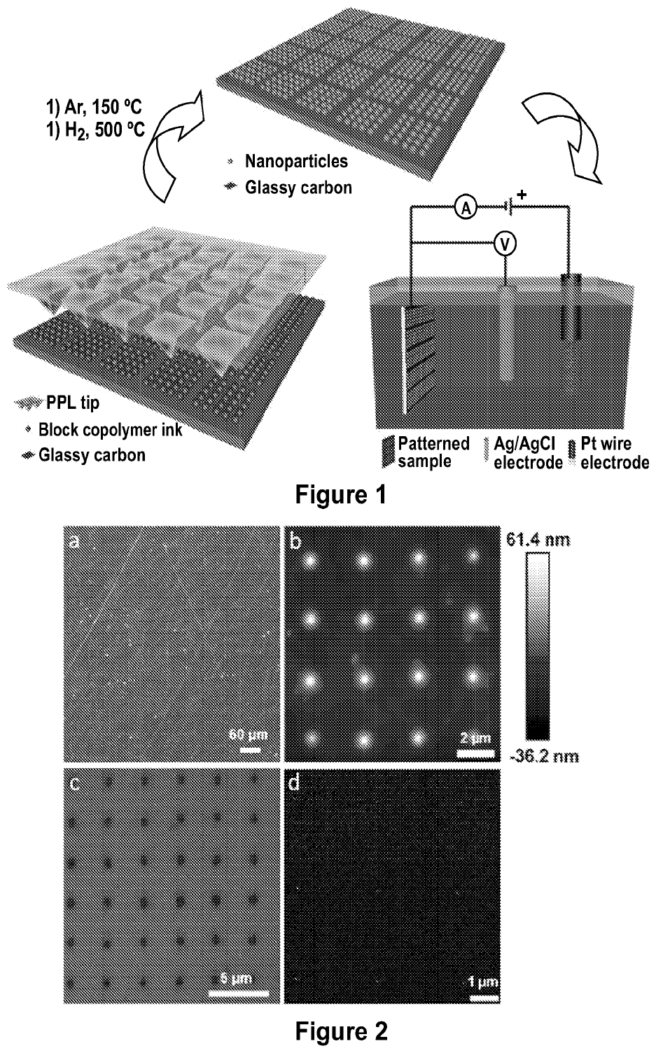

SPBCL confines metal precursors within individual polymer nanoreactors. Each nanoparticle grows by consuming the precursors within the polymer reactor, isolated from the growth of other nanoparticles. Therefore, the uniformity of nanoparticles in terms of size, phase structure, and composition can be exquisitely controlled. In a typical experiment (FIG. 1), the patterning ink is prepared by mixing the aqueous block copolymer solution (PEO-b-P2VP) with metal precursors (salts), followed by spin-coating onto the polymer pen lithography (PPL) tips. The PPL tips are then brought into contact with a glassy carbon substrate with an atomic force microscope (AFM) to make predesigned arrays of homogeneous nanoreactor domes (FIG. 2, a-c). Here, glassy carbon is used because it is a catalytically inert substrate and compatible with the SPBCL process. After the patterning process, the substrate is transferred into a tube furnace for a two-step thermal annealing procedure, where the metal precursors are aggregated and reduced. Throughout the SPBCL process, PEO-b-P2VP serves three functions: 1) to load the metal precursors, effectively acting as a solvent, 2) to facilitate the delivery of the patterning ink from tip to surface, and 3) to confine the nucleation and aggregation process within a small well-defined volume and direct the formation of single nanoparticles. Only one nanoparticle per nanoreactor typically forms (FIG. 2d).

PPL methods generally are disclosed in, e.g., WO 2009/132321, which is incorporated by reference in its entirety. Individual inking of tips, using the mold of the PPL tip array as an inkwell, wherein each inkwell can contain different inks for printing, is described generally in, e.g., WO 2010/124210, which is incorporated by reference in its entirety.

### Tip Arrays

The lithography methods disclosed herein employ a tip array formed from elastomeric polymer material. The tip arrays are non-cantilevered and include tips which can be designed to have any shape or spacing between them, as needed. The shape of each tip can be the same or different from other tips of the array. Contemplated tip shapes include spheroid, hemispheroid, toroid, polyhedron, cone, cylinder, and pyramid (e.g., trigonal or square). The tips are sharp, so that they are suitable for forming submicron patterns, e.g., less than about 500 nm. The sharpness of the tip is measured by its radius of curvature, and the radius of curvature of the tips preferred herein is below 1 μm, and can be less than about 0.9 μm, less than about 0.8 μm, less than about 0.7 μm, less than about 0.6 μm, less than about 0.5 μm, less than about 0.4 μm, less than about 0.3 μm, less than about 0.2 μm, less than about 0.1 μm, less than about 90 nm, less than about 80 nm, less than about 70 nm, less than about 60 nm, or less than about 50 nm, for example.

The tip array can be formed from a mold made using photolithography methods, which is then used to fashion the tip array using a polymer as disclosed herein. The mold can be engineered to contain as many tips arrayed in any fashion desired. The tips of the tip array can be any number desired, and contemplated numbers of tips include about 1000 tips to about 15 million tips, or greater. The number of tips of the tip array can be greater than about 1 million, greater than about 2 million, greater than about 3 million, greater than about 4 million, greater than 5 million tips, greater than 6 million, greater than 7 million, greater than 8 million, greater than 9 million, greater than 10 million, greater than 11 million, greater than 12 million, greater than 13 million, greater than 14 million, or greater than 15 million tips.

The tips of the tip array can be designed to have any desired thickness, but typically the thickness of the tip array (measured from the apex of the tip to the base of the tip) is about 50 nm to about 1 μm, about 50 nm to about 500 nm, about 50 nm to about 400 nm, about 50 nm to about 300 nm, about 50 nm to about 200 nm, or about 50 nm to about 100 nm.

The polymers can be any polymer having a compressibility compatible with the lithographic methods. Polymeric materials suitable for use in the tip array can have linear or branched backbones, and can be crosslinked or non-crosslinked, depending upon the particular polymer and the degree of compressibility desired for the tip. Cross-linkers refer to multi-functional monomers capable of forming two or more covalent bonds between polymer molecules. Non-limiting examples of cross-linkers include trimethylolpropane trimethacrylate (TMPTMA), divinylbenzene, di-epoxies, tri-epoxies, tetra-epoxies, di-vinyl ethers, tri-vinyl ethers, tetra-vinyl ethers, and combinations thereof.

Thermoplastic or thermosetting polymers can be used, as can crosslinked elastomers. In general, the polymers can be porous and/or amorphous. A variety of elastomeric polymeric materials is contemplated, including polymers of the general classes of silicone polymers and epoxy polymers. Polymers having low glass transition temperatures such as, for example, below 25° C. or more preferably below −50° C., can be used. Diglycidyl ethers of bisphenol A can be used, in addition to compounds based on aromatic amine, triazine, and cycloaliphatic backbones. Another example includes novolac polymers. Other contemplated elastomeric polymers include methylchlorosilanes, ethylchlorosilanes, phenylchlorosilanes, and polydimethylsiloxane (PDMS). Other materials include polyethylene, polystyrene, polybutadiene, polyurethane, polyisoprene, polyacrylic rubber, fluorosilicone rubber, and fluoroelastomers.

Further examples of suitable polymers that may be used to form a tip can be found in U.S. Pat. Nos. 5,776,748; 6,596,346; and 6,500,549, each of which is hereby incorporated by reference in its entirety. Other suitable polymers include those disclosed by He et al., Langmuir 2003, 19, 6982-6986; Donzel et al., Adv. Mater. 2001, 13, 1164-1167; and Martin et al., Langmuir, 1998, 14-15, 3791-3795. Hydrophobic polymers such as polydimethylsiloxane can be modified either chemically or physically by, for example, exposure to a solution of a strong oxidizer or to an oxygen plasma.

The polymer of the tip array has a suitable compression modulus and surface hardness to prevent collapse of the polymer during inking and printing, but too high a modulus and too great a surface hardness can lead to a brittle material that cannot adapt and conform to a substrate surface during printing. As disclosed in Schmid, et al., Macromolecules, 33:3042 (2000), vinyl and hydrosilane prepolymers can be tailored to provide polymers of different modulus and surface hardness. Thus, in some cases, the polymer is a mixture of vinyl and hydrosilane prepolymers, wherein the weight ratio of vinyl prepolymer to hydrosilane crosslinker is preferably at least about 5:1, 7:1, or 8:1 and preferably at most about 20:1, 15:1, or 12:1, for example in a range of about 5:1 to about 20:1, or about 7:1 to about 15:1, or about 8:1 to about 12:1.

The polymers of the tip array preferably will have a surface hardness in a range of about 0.2% to about 3.5% of glass, as measured by resistance of a surface to penetration by a hard sphere with a diameter of 1 mm, compared to the resistance of a glass surface (as described in Schmid, et al., Macromolecules, 33:3042 (2000) at p 3044). The surface hardness can be in a range of about 0.3% to about 3.3%, about 0.4% to about 3.2%, about 0.5% to about 3.0%, or about 0.7% to about 2.7%. The polymers of the tip array can have a compression modulus of about 10 MPa to about 300 MPa. The tip array preferably includes a compressible polymer which is Hookean under pressures of about 10 MPa to about 300 MPa. The linear relationship between pressure exerted on the tip array and the feature size allows for control of the indicia printed using the disclosed methods and tip arrays.

The tip array can include a polymer that has adsorption and/or absorption properties for the ink composition, such that the tip array acts as its own ink composition reservoir. For example, PDMS is known to adsorb patterning inks, see, e.g., US Patent Publication No. 2004/228962, Zhang, et al., Nano Lett. 4, 1649 (2004), and Wang et al., Langmuir 19, 8951 (2003).

The tip array can include a plurality of tips fixed to a common substrate and formed from a suitable polymer, such as one disclosed herein. The tips can be arranged randomly or in a regular periodic pattern (e.g., in columns and rows, in a circular pattern, or the like). The tips can all have the same shape or be constructed to have different shapes. The common substrate can include an elastomeric layer, which can include the same polymer that forms the tips of the tip array, or can include an elastomeric polymer that is different from that of the tip array. The elastomeric layer of the common substrate can have a thickness of about 50 μm to about 100 μm. The combination of tip array and common substrate can be affixed or adhered to a rigid support (e.g., glass, such as a glass slide). In various cases, the common substrate, the tip array, and/or the rigid support, if present, is translucent or transparent. In a specific case, each is translucent or transparent. The thickness of combination of the tip array and common substrate, can be less than about 200 μm, preferably less than about 150 μm, or more preferably about 100 μm. An example of an arrangement of tips fixed to an elastomeric layer common substrate is shown in FIG. 4.

### Inkwells

Inkwells are used to ink the tip arrays in the disclosed methods. These inkwell arrays can have a corresponding number, shape, and placement of wells for each tip of the tip array. In some embodiments, the inkwell arrays are repurposed from the molds used to prepare the tip arrays. In such embodiments, then, the dimensions and inter-well spacings of the wells of the inkwell are substantially or completely aligned with the tips of the tip array. Such substantial or complete alignment can allow for strict control of the inking of the tips with the selected inks, with little or no cross talk and/or cross contamination of one ink to another ink or to an incorrect set of tips, in a single inking step.

Standard photolithography techniques can be used to etch a mold having a selected number of tips, in a selected arrangement. The tip array can be formed by casting a polymer on the mold. After formation of the tip array from the mold, the mold can then be used as an inkwell array for the tip array. The wells of the inkwell array can be selectively filled with various inks, such that some tips of the tip array are inked with one ink while other tips are inked with a different ink. The wells can be filled by any means available, including, but not limited, using an inkjet printer. In some cases, the inkjet printer is an electrohydrodynamic inkjet printer. See also, e.g., U.S. Pat. Nos. 7,326,439; 7,168,791; 6,997,539; 7,273,270; and 7,434,912, US Patent Publication No. 2009/0133169.

In various embodiments, the inkwell array surface (e.g., the surface which will contact the ink) is treated with a fluorinated substance. Fluorination of the inkwell surface can decrease cross contamination of the inks in the different wells, by rendering the surface hydrophobic. The hydrophobic surface will reduce the size of the inked area and reduce lateral ink diffusion on the surface. In some cases, the inkwell surface is treated with a fluorosilane, such as 1H,1H,2H,2H-perfluorodecultrichlorosilane. Other contemplated fluorinated compounds include fluoropolymers, and silanes having at least one fluorine group (e.g., chlorosilanes, methylsilanes, methoxysilances, and ethoxysilanes with at least 1 F substituent, and preferably at least 2, at least 3, at least 4, or at least 5 F substituents). Examples include bis(trifluoropropyl)tetramethyldisiloxane and (heptadecafluoro-1,1,2,2-tetrahydrodecyl)triethoxysilane.

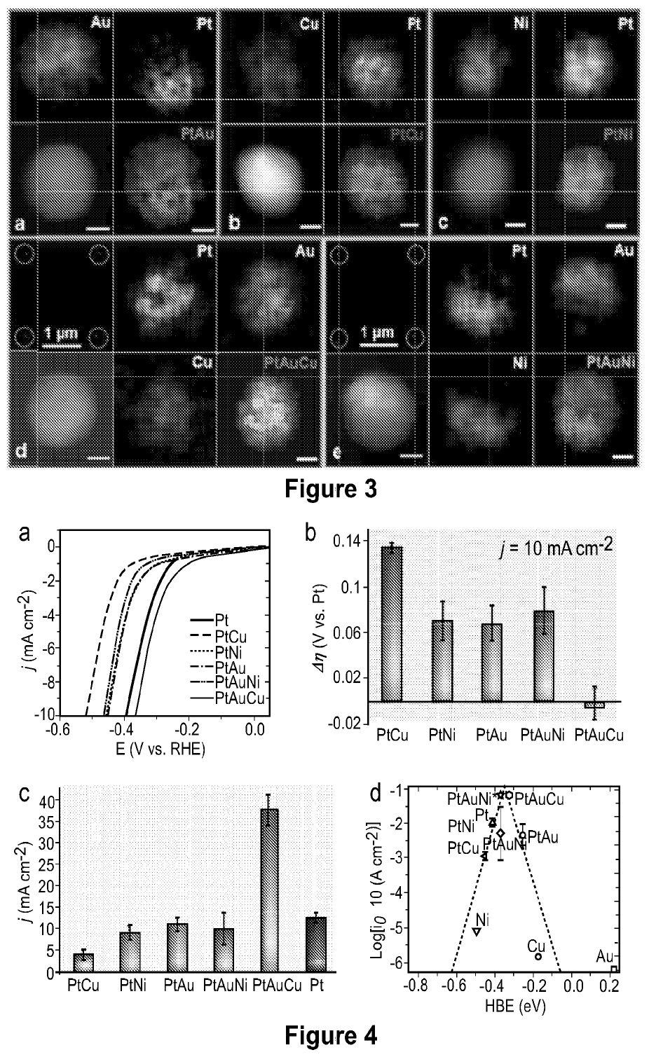

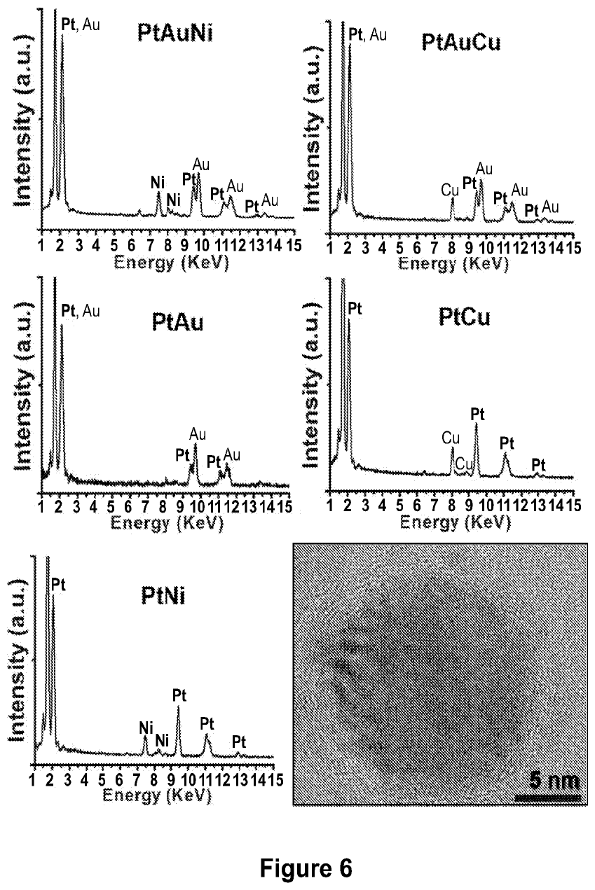

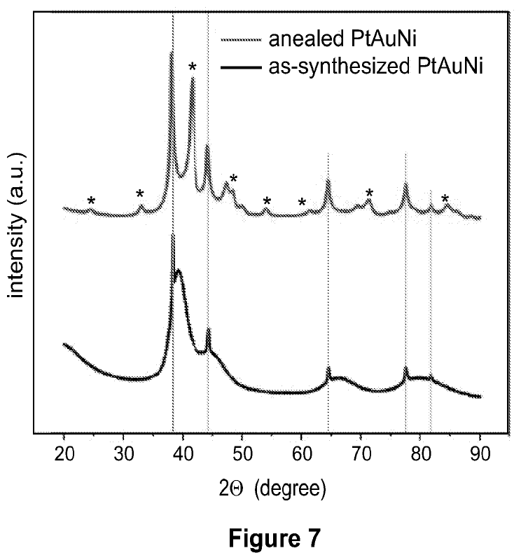

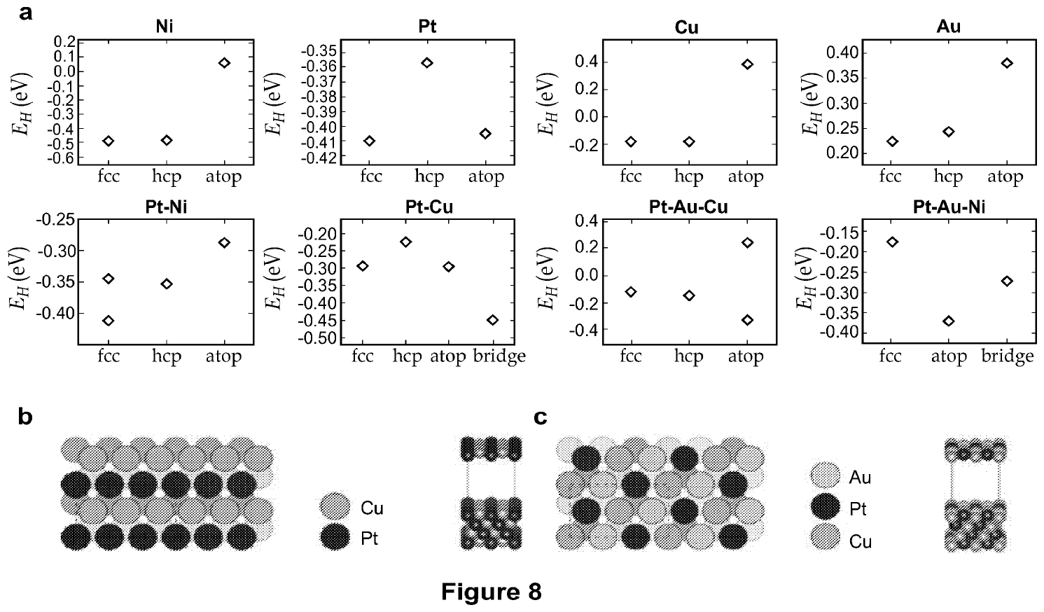

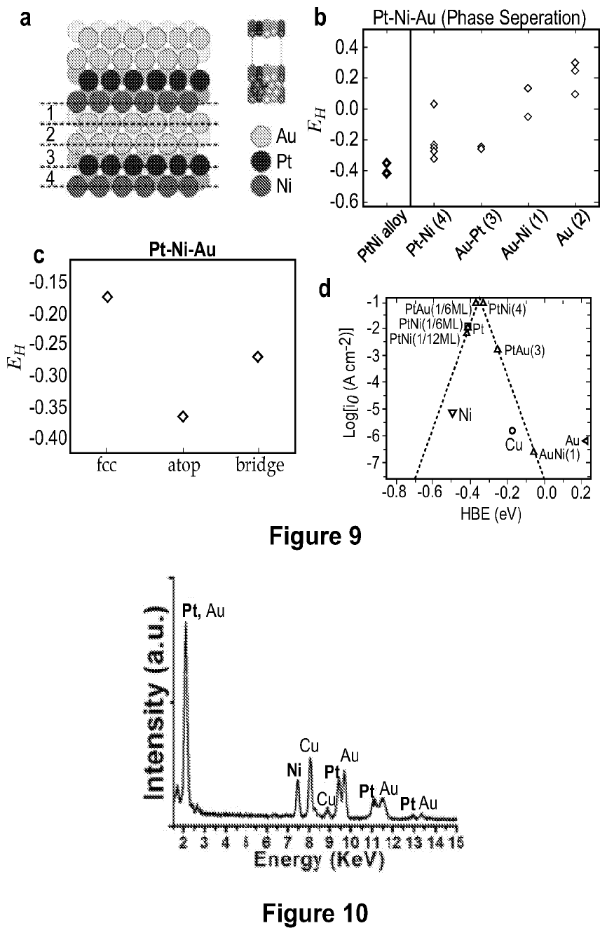

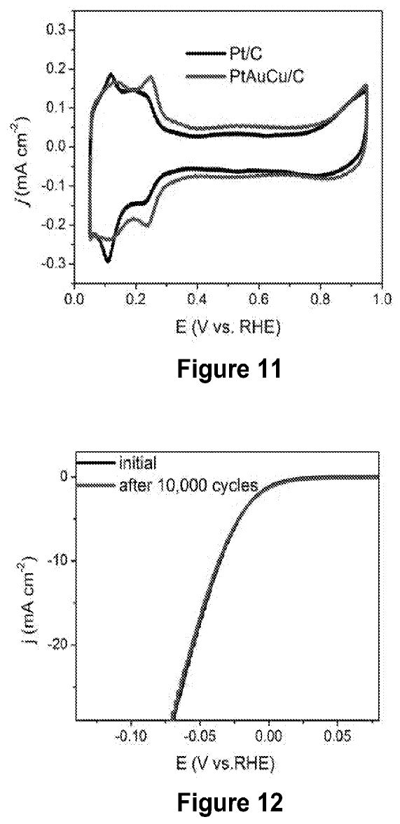

Pt, Au, Ni, and Cu were selected to verify the effectiveness of SPBCL as a catalyst screening and design platform, because they are common components of HER catalysts. TEM, HAADF-STEM, and EDS were employed to characterize SPBCL produced nanoparticles (FIG. 3 and FIG. 6). NP size is controlled, for example, in the 15-20 nm range by tuning the nanoreactor volume and metal loadings; particles less than 20 nm in diameter are typically used as HER catalysts. Monometallic nanoparticles are synthesized using, e.g., water-soluble H₂PtCl₆.6H₂O, HAuCl₄.3H₂O, Cu(NO₃)₂.3H₂O and Ni(NO₃)₂.6H₂O as precursors in the SPBCL process. The average stoichiometry of the final product is almost identical to the ratio of starting materials, due to the nanoreactor's ability to confine and direct the reaction towards single nanoparticle growth. Among the Pt-M (M=Au, Cu, Ni and Pt:M=1:1) binary nanoparticles, PtCu and PtNi have homogenous alloy phases since Cu and Ni are miscible with Pt, while PtAu is defined by a phase-segregated heterostructure that forms when the Au content is 50%, a result also supported by theory. At 1:1:1 Pt:Au:M (M=Ni, Cu) ratio, PtAuCu exhibits a homogenous alloy phase, while PtAuNi forms a phase-segregated heterostructure in which Pt and Ni are miscible but Au is immiscible with the other two metals in the particle (FIG. 3). Notably, regardless of phase (homogeneous alloy phase or phase-segregated), all SPBCL synthesized nanoparticles exhibit only one general structure under the conditions studied. Such high phase purity in multi-elemental particles is not easily realizable via conventional synthetic methods since it is challenging to synchronize the reduction of all metal ions in a precursor solution and to control site-selective nucleation. In addition, it is difficult to isolate nucleation events from the growth stage, and therefore difficult to prevent the formation of complex product mixtures. Indeed, in an attempt to prepare PtAuNi ternary nanoparticles via the most popular solution-phase-synthesis in one pot, a mixture of fcc Au and Pt-based Al alloy phases were obtained. In contrast, the SPBCL approach renders a high degree of both size control and phase purity of nanoparticles (FIG. 3). Such high uniformity is attractive for catalyst screening and design because it allows for correlation between catalytic properties and the chemical/physical properties of the catalysts.

### Computational Prediction of PtAuM Trimetallic Catalyst.

HER catalyst design has been well-established via the concept of volcano plots, which rationalize catalyst performance by connecting it to optimal adsorption properties. Pt is widely accepted as the most active monometallic catalyst towards the HER, since it is the element that is closest to the peak position of the volcano plot. Fe, Co, and Ni result in strong hydrogen adsorption while Au, Ag, and Cu exhibit weaker interactions with hydrogen. Therefore, none of them has comparable HER activity to Pt. However, adding a second or even third metal into Pt has proven to be a viable approach for tailoring the adsorption properties of Pt, in order to reach the Sabatier optimum. Using DFT, the HBE, the sole-descriptor of HER in an acidic environment, was examined on the (111) surface of monometallic, bimetallic and trimetallic catalysts. The computational results of monometallic catalysts are consistent with previous reports: Ni (−0.492 eV), which adsorbs hydrogen strongly is located on the left half part of the volcano plot, Pt (−0.410 eV) occupies a position that is slightly left to the peak of the volcano, while Cu (−0.172 eV) and Au (0.224 eV), with low HBE, are positioned on the right half of the plot. In the bimetallic system, in contrast with the Vegard's law for the determination of alloy lattice parameters, the HBE of a bimetallic alloy is not necessarily the average of its two components. For instance, PtCu has a HBE of −0.450 eV, which is even stronger than that of pure Pt, even though Cu itself weakly adsorbs hydrogen. While Pt-M bimetallic catalysts exhibit great tunability in their adsorption properties, they are nevertheless unable to reach the peak of the volcano plot. However, the Pt—Au-M trimetallic system offers an additional factor for the fine tuning of adsorption strength. Moreover, as the most noble metal, Au is expected to enhance the overall chemical stability of the trimetallic catalysts. The trimetallic system also helps to further reduce the Pt content, over a pure Pt catalyst. PtAuNi (−0.368 eV) and PtAuCu (−0.326 eV) with a homogenous alloy phase are identified as the optimal hydrogen adsorbents.

Experimental Verification with Nanoparticle Array Model Catalysts.

Because of their high uniformity, SPBCL-synthesized nanoparticle arrays are ideal model catalysts. Therefore, Pt, PtAu, PtCu, PtNi, PtAuNi and PtAuCu nanoparticle arrays were used to experimentally evaluate the prediction made by DFT. HER catalyst particles were tested with a three-electrode setup in which a glassy carbon disc with nanoparticle arrays was used as the working electrode, Ag/AgCl as the reference electrode, and a coiled Pt wire as the counter electrode. Au wire was also used as a counter electrode in order to avoid complications from possible redeposition of Pt onto the working electrode during the test cycles. PtAuCu exhibits the lowest overpotential among the listed multi-metallic catalysts (FIG. 4a and FIG. 4b), consistent with the DFT prediction. When the current density is normalized to the content of Pt in each catalyst, at an overpotential of 0.4 V, PtAuCu shows a current density of 37.4 mA cm⁻², that is more than three times the current density obtained with Pt (12.3 mA cm⁻²) (FIG. 4c). However, PtAuNi only exhibits a current density of 9.85 mA cm⁻², contrary to the DFT prediction. In the volcano plot (FIG. 4d), the PtAuNi alloy occupies the position close to the peak, denoted as PtAuNi*. Surprisingly, the actual exchange current density measured for SPBCL-synthesized PtAuNi is up to two orders of magnitude lower than the DFT predicted value. A closer inspection of the particles synthesized by SPBCL provides a clue to this discrepancy. Indeed, the DFT prediction is based on a PtAuNi homogenous alloy, and while PtNi can form a homogenous alloy, Au is immiscible with Pt or Ni, respectively, at a 1:1 ratio. Importantly, the EDS characterization of the trimetallic PtAuNi particle shows that it is a PtNi—Au heterostructure as opposed to a 3-element alloy. This observation underscores one of the major attributes of studying catalyst particles made by SPBCL. The high uniformity of such structures allows one to identify and study key structural features that are often missed in idealized and simplified computational approaches.

With this understanding in hand, a computational model was set up to mimic the observed PtNi—Au heterostructure. The surface of PtNi—Au is divided into four compositional regions: 1) Au—Ni, 2) Au, 3) Au—Pt, and 4) Pt—Ni. In each region, adsorbed hydrogen atoms bind with either one or two types of metal. all the unique fcc and hcp adsorption sites in each region were considered, with the adsorption coverage of 1/12 of a monolayer (ML). The computational results show that hydrogen adsorption near an interface is weaker than that on a uniform PtNi alloy surface, indicating that an interfacial effect indeed influences the HBE of PtNi even though Au atoms are not directly in contact with the hydrogen atoms. Under the influence of interfacial Au, Pt—Ni in region 4 exhibits the optimal HBE (−0.325 eV). In contrast, HBE on the sites in the other 3 regions is substantially weaker than the optimum value: −0.056 eV for Au—Ni in region 1, 0.092 eV in region 2, and −0.257 eV for Pt—Au in region 3. Therefore, compared to alloy-phase PtAuNi, phase-segregated PtNi—Au has fewer desired sites, which leads the significantly lower activity. Here, it is emphasized that in addition to size, shape, and composition, the phases of catalyst materials may be crucial for realizing desirable catalytic activity. Due to the unique phase purity rendered by SPBCL synthesis, one can unambiguously attribute the reduced HER activity to the phase segregation of PtAuNi. Despite desirable HER activity, the alloy phase PtAuNi is not easily prepared by any conventional known synthetic method. Taken together, one can conclude that the phase-segregated PtAuNi materials have limited value in HER.

In contrast, for the PtAuCu trimetallic system, although Pt and Au have poor miscibility, Cu is miscible with both Au and Pt. Therefore, PtAuCu can form a homogenous trimetallic alloy (FIG. 3), allowing one to electronically modify Pt with contributions from both Cu and Au. Hence, experimentally, such particles exhibit the highest current densities (FIG. 4).

### Design of Nanostructured PtAuCu as High-Performance HER Catalyst.

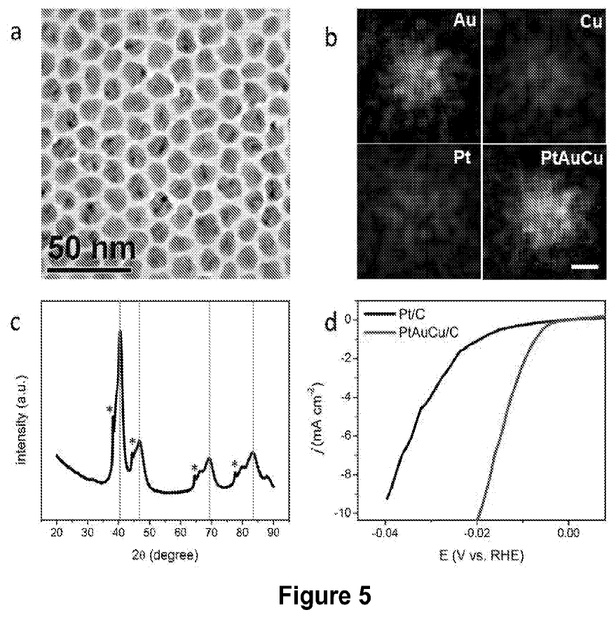

Although the DFT predictions and SPBCL model catalyst studies provide guidance with regard to optimum composition and structure for an HER catalyst, for them to be practically useful, catalysts in bulk amounts, which exhibit comparable properties, must be attainable. Therefore, the behavior of PtAuCu nanoparticles synthesized via a solution phase method was investigated. Platinum acetylacetonate, gold chloride, and copper acetylacetonate were co-reduced in the presence of oleylamine and oleic acid at 230° C., a common way of making trimetallic particles. The as-synthesized nanoparticles have a diameter of 12 nm and a composition of PtAuCu (FIG. 5a and FIG. 10). EDS mapping experiments show that Pt, Au, and Cu are homogenously distributed throughout the as-synthesized particles (FIG. 5b). Inductively coupled plasma mass spectrometry (ICP-MS) suggests a stoichiometry of Pt₃₇Au₂₉Cu₃₄, that is close to Pt:Au:Cu=1:1:1. In addition, XRD data (FIG. 5c) indicates a minor phase separation, but the predominant component is, indeed, PtAuCu. The lattice constant calculated from the XRD data is 0.388 nm, in agreement with the Vegard's law predicted value of 0.387 nm for the 1:1:1 Pt:Au:Cu stoichiometry. To test their HER activity, the as-synthesized PtAuCu nanoparticles were loaded onto carbon black (Cabot, Vulcan XC-72), and then thermally treated at 200° C. for 12 hours to remove organic capping agents. The PtAuCu/C catalyst was tested for HER and compared to the commercial Pt/C catalyst (FIG. 5d). At an overpotential of 20 mV, the specific activity for the PtAuCu/C catalyst is 10.3 mA cm⁻², which is more than 9 times that of Pt/C (1.08 mA cm⁻²). The mass activity (η=20 mV) for PtAuCu/C (3.33 A mg⁻¹ Pt) is over 7 times that of Pt/C (0.467 A mg⁻¹ Pt). The HER performance of PtAuCu/C in terms of mass activity may be further improved by optimizing the particle size, composition, phase purity, as well as tuning local fine structure (e.g. core-shell). Finally, the PtAuCu/C catalyst was cycled 10,000 times with a negligible drop in activity, which suggests this is also a long-lived catalyst as well.

SPBCL combined with DFT calculations are used as a new and powerful platform for catalyst discovery, design, and synthesis. The focus of this work has been on HER catalysts, and have been employed to identify a structure (1:1:1 PtAuCu alloy particles) that exhibits a mass activity 7 times greater than the best-known Pt/C catalyst (based on Pt content). However, these techniques and observations, in principle, can be extended to many other reactions, providing a means of discovering promising new catalyst structures as well as a method for refining them to achieve optimum performance. With recent developments in PPL technology, pen arrays with as many as 11 million tips enable large-scale fabrication of nanoparticle arrays with programmable specifications such as size, shape, and composition, providing a route to the high-throughput screening and discovery of new catalysts.

### EXAMPLES

### Materials:

Hexamethyldisilazane (HMDS) and hexane were obtained from Sigma-Aldrich. The block copolymer poly(ethylene oxide)-block-poly(2-vinylpyridine) (PEO-b-P2VP, Mn=2.8-b-1.5 kg mol⁻¹, polydispersity index=1.11) was purchased from Polymer Source. Metal precursors were purchased from Sigma-Aldrich. All the above materials were used as-received. Type M DPN pen arrays without gold coating were obtained from Nanoink. PPL arrays were acquired from TERA-print (Evanston, Ill.).

### Ink Preparation:

PEO-b-P2VP and metal compounds were dissolved in deionized water, and the solution was stirred for 2 days prior to use. The concentration of PEO-b-P2VP was 5 mg mL⁻¹. The pH of the solution was maintained between 3-4 by the addition of HNO₃.

### DPN Patterning Process:

For all DPN experiments, the DPN pen array was first dip-coated with the as-prepared block copolymer ink. After drying in air at room temperature, the pen array was loaded into a modified AFM instrument (XE-150, Park Systems) in a chamber with controlled humidity at 95%. The array was placed in contact with a substrate to make predesigned arrays. Both TEM grids with silicon nitride and carbon support films were used as the substrate and were treated for hydrophobicity prior to use. They were placed in a desiccator with a small vial of an HMDS and hexane mixture (1:1, v/v) overnight.

### PPL Patterning Process:

PPL arrays were first treated with an oxygen plasma at 60 W for 5 min, followed by spin-coating the ink for 60 s at 1000 rpm with a ramping rate of 500 rpm/s. After drying in air, the PPL arrays were placed into a modified AFM instrument (XE-150, Park Systems) and brought into contact with the substrate for patterning in a chamber with controlled humidity at 95%. Glassy carbon was spin coated with HMDS for 60 s at 1500 rpm before use.

### Thermal Treatment for Patterned Sample:

After the patterning, the patterned substrate was transferred into a tube furnace for annealing. The treatment was programmed as follows: under Ar gas flow, ramp to 150° C. within 1 h, hold at 150° C. for 48 h, cool down to 25° C. within 1 h, switch the atmosphere to H₂, ramp to 500° C. within 2 h, hold at 500° C. for 12 h, cool down to 25° C. within 2 h.

### Synthesis of PtAuCu Nanoparticles:

0.2 mmol Pt(acac)₂, 0.2 mmol HAuCl₄, and 0.2 mmol Cu(acac)₂ were dissolved in 10 mL benzyl ether, 7.36 mL oleylamine, and 1.25 mL oleic acid under Ar atmosphere. The reaction mixture was heated to the temperature of 230-240° C. for 30 minutes. After reaction, the solution was cooled down and the products were isolated by adding ethanol and centrifugation. The NCs were re-dispersed in hexane.

### Electrochemical Measurements:

The electrochemical measurements were performed in a three-electrode glass cell at 298K using an Epsilon Eclipse Workstation or a Metrohm AutoLab equipped with a rotating-disk electrode (RDE). The patterned sample (or nanoparticles loaded on XC-72), Ag/AgCl electrode, and coiled platinum (or gold) wire were used as the working, reference, and counter electrode respectively. The electrolyte was 0.5 M H₂SO₄ and was purged with Ar gas for 10 min prior to the measurements to remove the dissolved O₂. Polarization data were collected by cyclic voltammetry at a scan rate of 5 mV/s (20 mV/s for PtAuCu/C). All potentials were calibrated versus a reversible hydrogen electrode (RHE).

### Characterization:

Optical images were taken with a Zeiss imager. M2m. SEM images were taken with Hitachi SU-8030 field emission scanning electron microscope at an acceleration voltage of 5 kV and a current of 15 μA. STEM images were taken with Hitachi HD-2300 scanning transmission electron microscope at an acceleration voltage of 200 kV. The EDS spectra and mapping were obtained with Thermo Scientific NSS 2.3. TEM images were taken with Hitachi 8100 at an acceleration voltage of 200 kV. HR-TEM images were taken with JEOL 2100F at an acceleration voltage of 200 kV. Atomic force microscope (AFM) measurements were performed on a Dimension Icon (Bruker) to obtain 3D profiles of the patterns. X-ray diffraction (XRD) spectra were collected on a Rigaku Ultima with a Cu Kα source. Inductively coupled plasma mass spectrometry (ICP-MS) was collected on a Thermo iCAP Q mass spectrometer.

### Computation:

HBE calculations are based on DFT as implemented in the Vienna ab initio Simulation Package (VASP) using the projector-augmented wave (PAW) method. All calculations were performed with the RPBE exchange-correlation functional on periodically repeated metal slabs⁴⁴. A slab model with 4 atomic layers with a (3×2) unit cell and a vacuum region of 12 Å in thickness is used to calculate the hydrogen binding energies on (111) surfaces of pure metal (Ni, Pt, Cu, Au), bi-metallic (Pt—Ni, Pt—Cu) and tri-metallic (Pt—Cu—Au) systems. The bottom two layers are fixed and the top two layers are allowed to relax. An energy cutoff of 400 eV is used for the plane wave basis set used to represent the electronic wave functions. Brillouin-zone integrations are sampled using F-centered k-point meshes corresponding to a 6×10×1 grid. Spin polarization and dipole correction are included in all DFT calculations. The hydrogen binding energies are calculated by E_{H}=E_{H-slab}−E_{slab}−½E_{H2(g)} where E_{H} is the binding energy of atomic hydrogen on the given slab, E_{H-slab} is the total energy of the slab with ⅙ ML hydrogen adsorbed, E_{slab} is the total energy of the slab in vacuum, and E_{H2(g)} is the energy of an isolated hydrogen molecule in the gas phase.

The following Table 1 shows physical characteristics of nanoparticles synthesized as disclosed herein. Tables 2 and 3 below show adsorption sites for pure metal, bimetallic, and trimetallic surfaces, and the calculated hydrogen binding energies for each.

TABLE 1
The size and composition of SPBCL synthesized nanoparticles

| | Size (nm) | Composition |
|---|---|---|
| PtNi | 18 ± 2 | Pt₄₇Ni₅₃ |
| PtCu | 18 ± 3 | Pt₄₉CU₅₁ |
| PtAu | 18 ± 2 | Pt₄₆AU₅₄ |
| PtAuCu | 18 ± 2 | Pt₃₀AU₃₆CU₃₄ |
| PtAuNi | 18 ± 2 | Pt₃₂Au₃₆Ni₃₂ |

TABLE 2
Number of adsorption sites considered for different systems

| | PURE METAL | BI-METALLIC | TRI-METALLIC |
|---|---|---|---|
| SITE | SURFACE | SURFACE | SURFACE |
| FCC | 1 | 2 | 1 |
| HCP | 1 | 2 | 3 |
| ATOP | 1 | 2 | 3 |

TABLE 3
Hydrogen binding energies at most stable
adsorption site for different systems.

| System | E_{H} (eV) | Adsorption site |
|---|---|---|
| Ni | −0.492 | fcc |
| Pt | −0.410 | fcc |
| Cu | −0.172 | fcc/hcp |
| Au | 0.224 | fcc |
| PtNi | −0.411 | fcc (1Pt & 2Ni) |
| PtCu | −0.450 | bridge (2 Pt) |
| PtAuCu | −0.326 | atop (Pt) |
| PtAuNi | −0.368 | atop (Pt) |

### REFERENCES

1. Bratlie, et al. Nano Lett. 7, 3097-3101 (2007).
2. Li, et al. Nano Lett. 10, 2289-2295 (2010).
3. Somorjai, et al. Ind. Eng. Chem. Fundam. 25, 63-69 (1986).
4. Jacobs, et al. Catal. Lett. 37, 131-136 (1996).
5. Habas, et al. Nat. Mater. 6, 692-697 (2007).
6. Chen, et al. Science 343, 1339-1343 (2014).
7. Zuburtikudis, et al. Science 258, 1337-1339 (1992).
8. Somorjai. Chem. Rev. 96, 1223-1235 (1996).
9. Bell. Science 299, 1688-1691 (2003).
10. Burda, et al. Chem. Rev. 105, 1025-1102 (2005).
11. Lee, et al. Angew. Chem. Int. Ed. 45, 7824-7828 (2006).
12. Stamenkovic, et al. Science 315, 493-497 (2007).
13. Herzing, et al. Science 321, 1331-1335 (2008).
14. Lee, et al. Nat. Mater. 8, 132-138 (2009).
15. Peng, et al. Nano Today 4, 143-164 (2009).
16. Kang, et al. J. Am. Chem. Soc. 135, 2741-2747 (2013).
17. Wang, et al. J. Phys. Chem. C 113, 19365-19368 (2009).
18. Zhang, et al. Science 349, 412-416 (2015).
19. Tian, et al. Science 316, 732-735 (2007).
20. Bu, et al. Science 354, 1410 (2016).
21. Si, et al. Angew. Chem. Inter. Ed. 47, 2884-2887 (2008).
22. Greeley, et al. Nat. Mater. 5, 909-913 (2006).
23. McCrory, et al. J. Am. Chem. Soc. 137, 4347-4357 (2015).
24. Chu, et al. Nature 488, 294-303 (2012).
25. Turner. Science 305, 972 (2004).
26. Sheng, et al. Nat. Commun. 6, 5848 (2015).
27. Kitchin, et al. J. Chem. Phys. 120, 10240-10246 (2004).
28. Stamenkovic, et al. Angew. Chem. Inter. Ed. 45, 2897-2901 (2006).
29. Nørskov, et al. Nat. Chem. 1, 37-46 (2009).
30. Lv, et al. J. Am. Chem. Soc. 137, 5859-5862 (2015).
31. Lu, et al. Nat. Commun. 6, 6567 (2015).
32. Zhang, et al. Science 315, 220-222 (2007).
33. Kang, et al. Nano Lett. 14, 6361-6367 (2014).
34. Wang, et al. Nano Lett. 11, 919-926 (2011).
35. Chai, et al. Proc. Natl. Acad. Sci. U.S.A. 107, 20202-20206 (2010).
36. Chen, et al. J. Am. Chem. Soc. 137, 9167-9173 (2015).
37. Chen, et al. Science 352, 1565-1569 (2016).
38. Huo, et al. Science 321, 1658-1660 (2008).
39. Subbaraman, et al. Science 334, 1256-1260 (2011).
40. Ruban, et al. Phys. Rev. B 59, 15990-16000 (1999).
41. Chen, et al. J. Phys. Chem. C 115, 17915-17924 (2011).
42. Murray, et al. Annu. Rev. Mater. Sci. 30, 545-610 (2000).
43. Kresse, et al. Phys. Rev. B 54, 11169-11186 (1996).
44. Kresse, et al. Comput. Mater. Sci. 6, 15-50 (1996).
45. Kresse, et al. Phys. Rev. B 59, 1758-1775 (1999).
46. Hammer, et al. Phys. Rev. B 59, 7413-7421 (1999).
47. Denton, et al. Phys. Rev. A 43, 3161 (1991).
48. Wang, et al. Acs Catal. 2, 891-898 (2012).

1. A catalyst comprising PtAuX and having a hydrogen binding energy lower than 0.0 eV, wherein X is a transition metal other than Pt and Au.

2. The catalyst of claim 1, having a hydrogen binding energy from −0.1 to −0.6 eV.

3. The catalyst of claim 1, having a hydrogen binding energy from −0.2 to −0.4 eV.

4. The catalyst of claim 1, wherein X is Cu or Ni.

5. The catalyst of claim 1, wherein the catalyst is an alloy or is in the form of a phase-separated heterostructure.

6. The catalyst of claim 5, wherein the alloy is homogeneous.

7. The catalyst of claim 5, in the form of a phase-separated heterostructure.

8. The catalyst of claim 1, in a 1:1:1 molar ratio.

9. The catalyst of claim 1, in the form of a nanoparticle.

10. The catalyst of claim 9, wherein the nanoparticle has a diameter of 10 to 20 nm.

11. The catalyst of claim 1 loaded onto a support.

12. The catalyst of claim 11, wherein the support is carbon black or glassy carbon.

13. A method of reducing an organic compound comprising contacting the compound with a reducing agent (e.g., H2) in the presence of the catalyst of claim 1 to form a reduced organic compound.

14. A method comprising
(a) coating a tip of a tip array with an ink comprising a metal precursor and a polymer solution;
(b) contacting a substrate surface for a contacting period of time and at a contacting pressure with the coated tip of the tip array to deposit the ink onto the substrate surface to form a set of indicia, the indicia of being substantially uniform in size;
(c) heating the tip array under conditions sufficient to form nanoparticles from the metal precursor; and
(d) using the substrate surface comprising the nanoparticles in a three-electrode cell to assess the nanoparticles as catalysts of a hydrogen evolution reaction.

15. The method of claim 14, wherein a second tip of the tip array is coated with a second ink comprising a second metal precursor, and forms a second nanoparticle.

16. The method of claim 14, further comprising contacting the substrate surface with a tip array coated with a second ink comprising a second metal precursor, prior to step (c), and the second metal precursor forms a second nanoparticle.

17. The method of claim 14, wherein the substrate comprises glassy carbon.

18. The method of claim 14, wherein the polymer solution comprises PEO-b-P2VP.

19. The method of claim 14, wherein the metal precursor comprises two or more metals or metal salts.

20. The method of claim 19, wherein the metal precursor comprises three metals or metal salts.

21. The method of claim 14, wherein the conditions sufficient to form nanoparticles comprise a two-step annealing process.

22. The method of claim 14, wherein the tip array comprises an elastomeric polymer material.
